(19) United States
(12) Patent Application Publication
(10) Pub. No.: US 2019/0115342 A1
(43) Pub. Date: Apr. 18, 2019

(54) HIGH QUALITY FACTOR FIN METAL OXIDE SEMICONDUCTOR VARACTOR WITH IMPROVED NUMBER OF FINS

(71) Applicant: QUALCOMM Incorporated, San Jose, CA (US)

(72) Inventors: Ye LU, San Diego, CA (US); Yun YUE, San Diego, CA (US)

(21) Appl. No.: 15/862,533

(22) Filed: Jan. 4, 2018

Related U.S. Application Data
(60) Provisional application No. 62/573,070, filed on Oct. 16, 2017.

(51) Int. Cl. H01L 27/08; H01L 29/94; H01L 29/66; H01L 21/822; H01L 21/66; H01L 29/06; H01L 27/02

(52) U.S. Cl. CPC H01L 27/0808; H01L 29/94; H01L 29/66174; H01L 27/0207; H01L 22/14; H01L 29/0692; H01L 21/822

(57) ABSTRACT

A FinMosVar (fin metal oxide semiconductor (MOS) varactor) has an improved number of fins. The number of fins are determined based on a measured or calculated gate resistance of the FinMosVar and a measured or calculated capacitance of the FinMosVar. The number of fins is less than twenty (20) fins. The FinMosVar also includes a source region, a drain region and a channel region. The drain region has a same type of doping as the source region. The channel region has the same type of doping as the source region.

### CROSS-REFERENCE TO RELATED APPLICATION

The present application claims the benefit of U.S. Provisional Patent Application No. 62/573,070, filed on Oct. 16, 2017, and titled “HIGH QUALITY FACTOR FIN METAL OXIDE SEMICONDUCTOR VARACTOR WITH IMPROVED NUMBER OF FINS,” the disclosure of which is expressly incorporated by reference herein in its entirety.

### TECHNICAL FIELD

The present disclosure generally relates to semiconductor fabrication. More specifically, the present disclosure relates to improving a quality (Q)-factor of metal oxide semiconductor (MOS) varactors by selecting a number of fins.

### BACKGROUND

Mobile radio frequency (RF) chips (e.g., mobile RF transceivers) have migrated to a deep sub-micron process node due to cost and power consumption considerations. The design complexity of mobile RF transceivers is further complicated by added circuit function to support communication enhancements. Further design challenges for mobile RF transceivers include analog/RF performance considerations, such as mismatch, noise, and other performance considerations. The design of these mobile RF transceivers includes the use of a voltage controlled capacitance and/or a tunable capacitor (e.g., a varactor), for example, to provide a voltage controlled oscillator.

Digitally controlled or voltage controlled oscillators may have very sensitive nodes where thermal noise may be converted to phase noise around an oscillation frequency. Biasing these nodes may negatively affect the oscillator by lowering the quality (Q)-factor of a tank circuit, thus increasing its phase noise. Some systems can implement resistive circuitry to reduce varactor noise contribution.

### SUMMARY

A FinMosVar (fin metal oxide semiconductor (MOS) varactor) may include a number of fins determined based on a calculated gate resistance of the FinMosVar and a calculated capacitance of the FinMosVar. The number of fins is less than twenty (20) fins. The FinMosVar may further include a source region, a drain region, and a channel region. The drain region includes a same type of doping as the source region. Also, the channel region includes the same type of doping as the source region.

A method of manufacturing a selected FinMosVar (fin metal oxide semiconductor (MOS) varactor) may include measuring and/or calculating gate resistances (Rgate) for multiple possible FinMosVar devices, each with a different number of fins. The method may further include measuring and/or calculating a FinMosVar capacitance for each of the multiple FinMosVar devices with the different number of fins. The method also includes determining a desired number of fins for the selected FinMosVar based on the measured and/or calculated gate resistances and the FinMosVar capacitances. Furthermore, the method includes fabricating the selected FinMosVar using the determined number of fins.

A FinMosVar (fin metal oxide semiconductor (MOS) varactor) may include a number of fins determined based on a calculated gate resistance of the FinMosVar and a calculated capacitance of the FinMosVar. The number of fins is less than twenty (20) fins. The FinMosVar may further include a source region, a drain region, and means for carrying charge in between the drain region and the source region. The drain region includes a same type of doping as the source region. Also, the charge carrying means includes the same type of doping as the source region.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a wireless device communicating with a wireless communication system.

FIG. 2 shows a block diagram of the wireless device in FIG. 1, according to an aspect of the present disclosure.

FIG. 3 shows various gate resistance components in a fin structure, including vertical and horizontal components.

FIG. 4A is an illustration of a FinMosVar (fin metal oxide semiconductor (MOS) varactor) device having a fin structure with twelve fins, according to aspects of the present disclosure.

FIG. 4B is an illustration of multiple FinMosVar (fin metal oxide semiconductor (MOS) varactor) devices, with each device including a fin structure having twelve fins, according to aspects of the present disclosure.

FIG. 5A illustrates a corresponding cross-sectional view through a fin of the FinMosVar, according to aspects of the present disclosure.

FIG. 5B illustrates a top view of an exemplary FinMosVar, according to aspects of the present disclosure.

FIG. 6A illustrates a corresponding cross-sectional view through a gate of the FinMosVar, according to aspects of the present disclosure.

FIG. 6B illustrates a top view of an exemplary FinMosVar, according to aspects of the present disclosure.

FIG. 7 depicts a simplified method of manufacturing a selected FinMosVar (fin metal oxide semiconductor (MOS) varactor), according to aspects of the present disclosure.

FIG. 8 is a block diagram showing an exemplary wireless communication system in which a configuration of the disclosure may be advantageously employed.

FIG. 9 is a block diagram illustrating a design workstation used for circuit, layout, and logic design of the transistor according to aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Mobile radio frequency (RF) chips (e.g., mobile RF transceivers) have migrated to a deep sub-micron process node due to cost and power consumption considerations. The design complexity of mobile RF transceivers is further complicated by added circuit function to support communication enhancements. Further design challenges for mobile RF transceivers include analog/RF performance considerations, including mismatch, noise, and other performance considerations. The design of these mobile RF transceivers includes the use of a voltage controlled capacitance and/or a tunable capacitor (e.g., a varactor), for example, to provide a voltage controlled oscillator. Varactors may also be known as variable capacitance diodes.

A varactor is an example of an electrical device used to store energy (e.g., charge) in an electrical field between closely spaced capacitor plates according to a capacitance value. This capacitance value provides a measure of the amount of charge stored by the capacitor at a certain voltage. In addition to their charge storing capability, capacitors are also useful as electronic filters because they enable differentiation between high frequency and low frequency signals. In a conventional varactor, a plate width modulates to vary an electric field formed between the capacitor plates. Varactors provide an electrically controllable capacitance that can be used in tuned circuits. While the use of varactors is advantageous in many applications (e.g., due to small size and reduced cost), varactors generally exhibit a lower quality (Q)-factor and non-linearity because varactors are asymmetric devices.

Transceivers for various radio access technologies (e.g., 3G, 4G, and 5G) specify varactors (e.g., metal oxide semiconductor (MOS) varactors) with a high quality factor, especially at high frequencies (e.g., >1 GHz). These varactors may be used in voltage controlled oscillators (VCOs). One figure of merit (FoM) for VCOs is phase noise. An increased phase noise causes a decrease in signal-to-noise ratio (SNR), limits receiver sensitivity, and causes a degradation in error vector magnitude of a transmit chain.

One of the contributors to the phase noise of the VCO is the varactor used in a capacitor bank of an inductor-capacitor tank (LC tank) of the VCO. For example, the phase noise of the VCO increases with a decrease in a quality factor of the varactor. This increase in phase noise of the VCO is particularly noticeable at higher frequencies. The increase in phase noise results in degraded receiver sensitivity and reduced transmitter error vector magnitude. Accordingly, it is desirable to improve the phase noise of the VCO.

One way to improve the phase noise of the VCO is to improve the quality factor of the varactor. The varactor may be fabricated in accordance with a three-dimensional fin field effect transistor (finFET) process or any other process technology such as planar or metal oxide semiconductor technologies that implement multiple gate stacks with different resistances. In one aspect of the disclosure, the process technology may be a fourteen (14) nanometer finFET process. An integrated circuit (IC) (e.g., including a VCO) may be formed based on the process technology. The process technology may enable multiple (e.g., two) types of gate stacks instead of only one type of gate stack. The IC may be a varactor (e.g., a MOS varactor) that has a gate stack with the first resistance. In one aspect of the disclosure, the IC is included in a transceiver circuit having a voltage controlled oscillator or any other phase locked loop based circuit.

A process technology that implements multiple gate stacks with different resistances may be a fourteen nanometer (14 nm) finFET (e.g., 14 low power compact (LPC)-radio frequency (RF)) process technology. The 14 LPC-RF process technology is a metal (or conductive material) work function based process technology with dual gate stacks. The IC may be formed based on the 14 LPC-RF process technology. In 14 LPC-RF process technology, however, a quality (Q)-factor of metal oxide semiconductor (MOS) varactors is not optimized (e.g., the Q-factor is not high enough). The low Q-factor of fin MOS varactors impacts circuit performance, such as increasing the phase noise of voltage controlled oscillator (VCO) circuits.

Aspects of the present disclosure are directed to optimizing or improving a number of fins of a semiconductor component designed according to a fin process technology, such as 14 LPC-RF process technology. Other examples of the fin process technology include sixteen nanometer (nm), fourteen nanometer, ten nanometer, seven nanometer, and five nanometer fin process technologies. In one aspect, the semiconductor component is a metal oxide semiconductor (MOS) varactor (FinMosVar). Some aspects of the present disclosure may be implemented in the design phase prior to fabricating the FinMosVar.

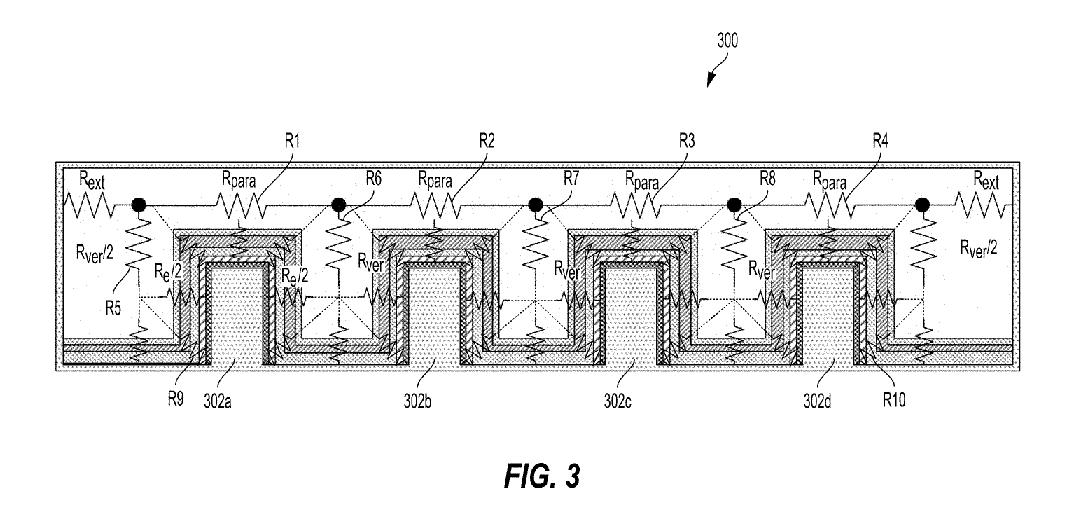

A property of a FinMosVar is its Q-factor. The Q-factor is proportional to 1/C×R, where C is the capacitance of the FinMosVar and R is the parasitic resistance of the FinMosVar. The parasitic resistance R is mainly dominated by gate resistance (Rgate) in advanced CMOS processes. A planar structure of a conventional MOSFET varactor (e.g., planar MOSFET varactor) has only one resistance (e.g., horizontal resistance) and therefore may not achieve an optimal resistance. However, the gate resistance of a fin structure (e.g., the FinMosVar) may include a vertical resistance and a horizontal resistance, as shown in FIG. 3.

Conventional implementations for accurately determining a number of fins for a FinMosVar may not account for gate resistance and FinMosVar capacitance because of complexities associated with calculating/measuring these resistances and capacitances. For example, a complexity of measuring gate resistance (a major part of parasitic resistance) is that accurate input gate resistance is measured as a RF quantity and not measured in DC. Thus, the measurement specifies GSG (ground-signal-ground) test structures that are area consuming and complex to design. A complexity of measuring capacitance is that usually capacitance measurement is an alternating current (AC) measurement, and the accuracy itself is limited, so a system with very small capacitance is difficult to measure.

These complexities become more acute when attempting to accurately measure or calculate small capacitances associated with a smaller number of fins. Moreover, foundries do not routinely perform measurements and calculations of FinMosVar capacitances and gate resistances under radio frequency conditions. This follows because the devices fabricated by these foundries are generally devices that are not radio frequency devices (e.g., logic circuits for which Q-factor is not important) or the foundries have a vested interest in testing the devices under specific radio frequency conditions.

An improved or optimized number of fins for a FinMosVar may be determined by calculating and/or measuring gate resistance (Rgate) of multiple FinMosVar devices, each with a different number of fins. In addition, capacitance is calculated and/or measured for each of the multiple FinMosVar devices with the different number of fins. The optimized or improved number of fins for a FinMosVar is then determined based on the measured and/or calculated gate resistances and the measured and/or calculated FinMosVar capacitances. For example, the desired number of fins may be selected to achieve a reduced FinMosVar capacitance.

In some aspects, a reduction of the number of fins from twenty or more to between eleven and thirteen results in a FinMosVar capacitance reduction of about forty percent for a given number of gates (e.g., sixty). The reduction in FinMosVar capacitance achieves a reduction in size of the FinMosVar because a smaller capacitor can be used for the FinMosVar. Similarly, a reduction of the number of fins from twenty or more to between eleven and thirteen results in a gate resistance reduction of about fifteen percent for a given number of gates (e.g., sixty) of the FinMosVar. This reduction in the gate resistance also achieves a reduction in size of the FinMosVar because a smaller resistance can be used for the FinMosVar. Moreover, the Q-factor of the FinMosVar is increased or improved as a result of the reduction of the FinMosVar capacitance and the gate resistance.

An improved or optimized FinMosVar may be manufactured or fabricated using the improved or optimized number of fins. The FinMosVar device has a drain region, a source region, and a channel region with a same type of doping (e.g., N-type or P-type). In some aspects, a FinMosVar device may include multiple fin structures in parallel, each with less than twenty fins. Each of the parallel fin structures may include eleven to thirteen fins. In one aspect, a first fin structure may be coupled to a second fin structure via a back end of line connection. For example, drains of the first fin structure may be coupled to drains of the second fin structure. Sources of the first fin structure may be coupled to sources of the second fin structure. Similarly, gates of the first fin structure may be coupled to gates of the second fin structure.

The impedance (e.g., resistance) of the fin structure changes with the device geometry (e.g., for a specific number of fins and a specified number of gates) of the FinMosVar. At a certain geometry, optimal or improved gate resistance, and FinMosVar capacitance enhance radio frequency performance, especially under millimeter wave (mmW) technology conditions.

In some aspects of the present disclosure, the gate resistance and the FinMosVar capacitance are obtained while accounting for radio frequency conditions. In this case, the number of fins are determined while accounting for the radio frequency conditions that specify an optimal/improved quality factor.

The radio frequency conditions may include five gigahertz (5 GHz) radio frequency conditions. The radio frequency conditions may also include a 5G system at 28 GHz and above, a long-term evolution (LTE) system, a code division multiple access (CDMA) system, a global system for mobile communications (GSM) system, a wireless local area network (WLAN) system, millimeter wave (mmW) technology, or some other wireless system. A CDMA system may implement wideband CDMA (WCDMA), time division synchronous CDMA (TD-SCDMA), CDMA2000, or some other version of CDMA.

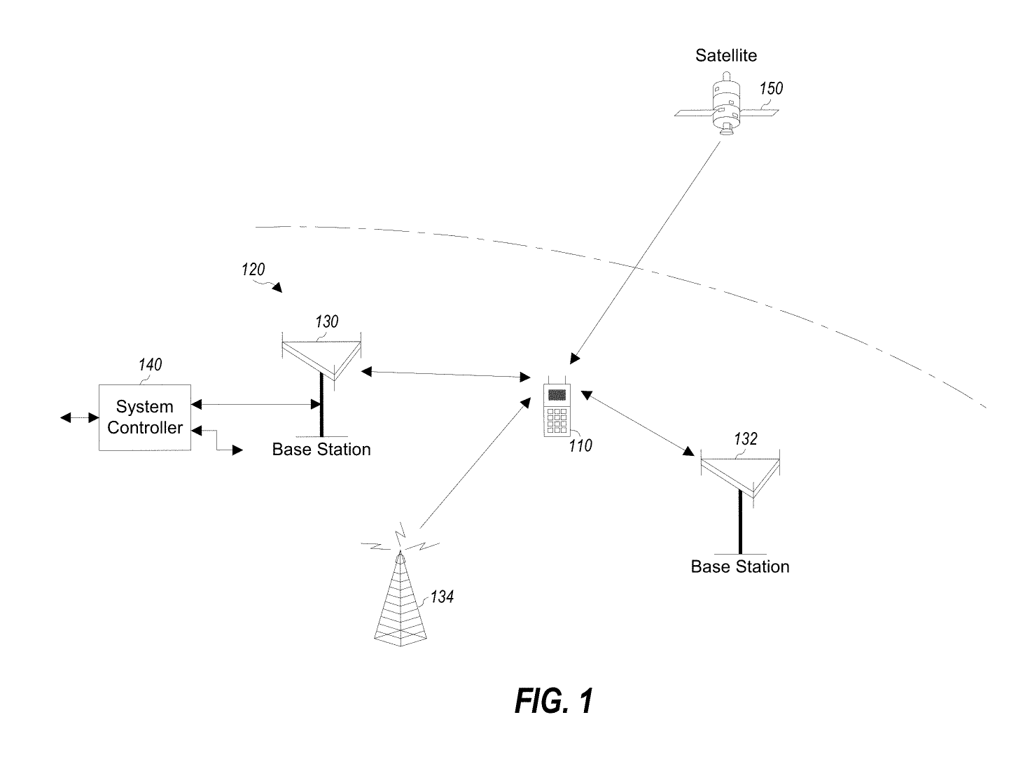

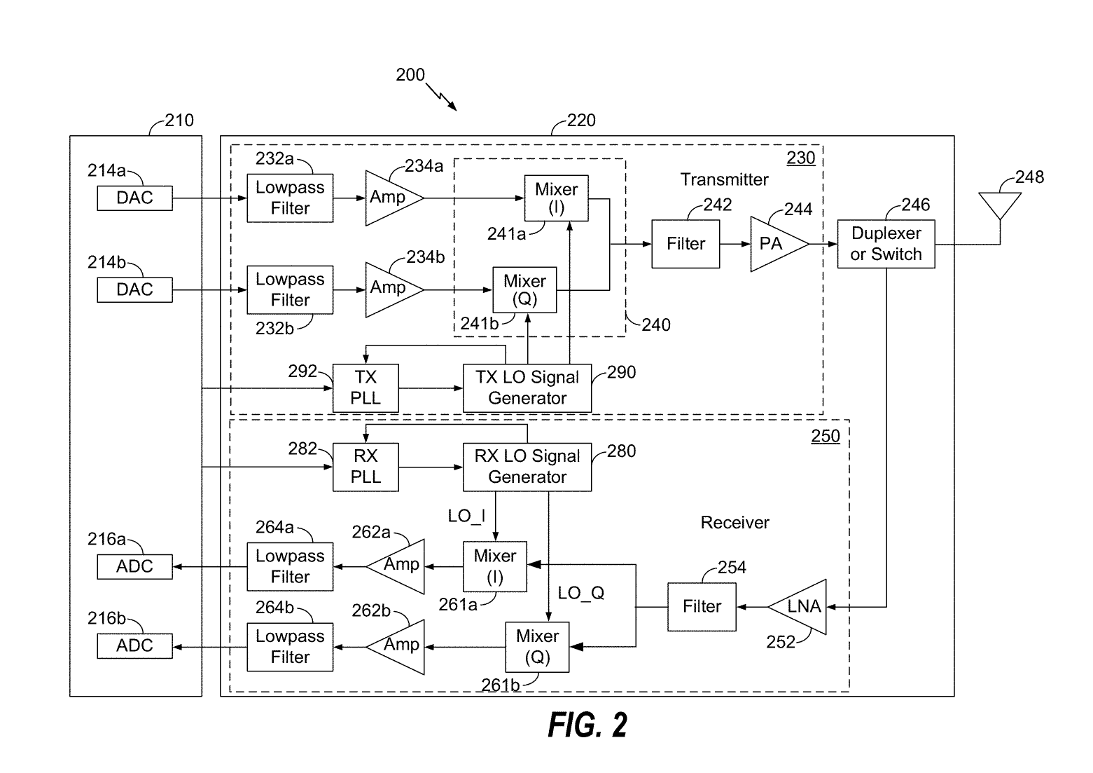

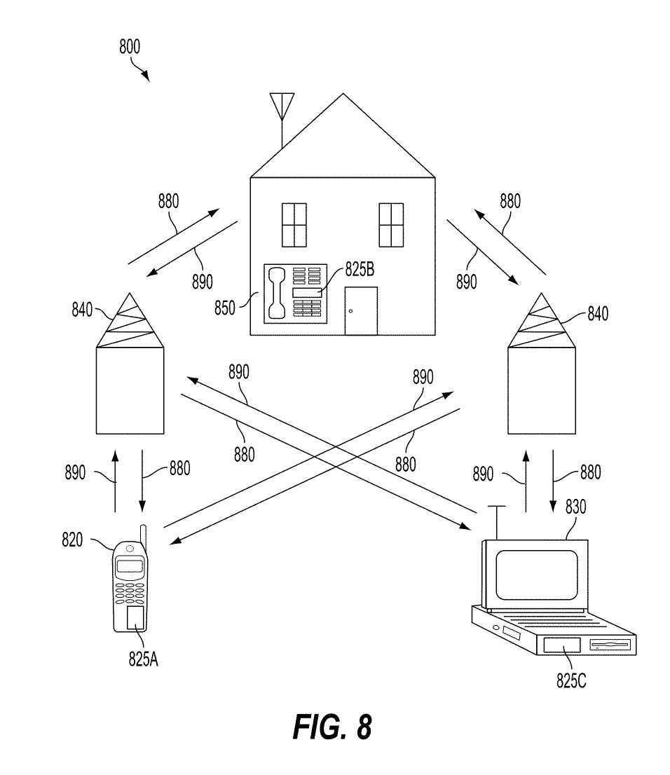

The devices of the present disclosure may be implemented in the systems of FIGS. 1 and 8. More specifically, the devices may be implemented in the wireless device of FIG. 2.

FIG. 1 shows a wireless device 110 communicating with a wireless communication system 120. The wireless device 110 may include the FinMosVar designed according to aspects of the present disclosure. The wireless communication system 120 may be a 5G system, a long-term evolution (LTE) system, a code division multiple access (CDMA) system, a global system for mobile communications (GSM) system, a wireless local area network (WLAN) system, or some other wireless system. A CDMA system may implement wideband CDMA (WCDMA), time division synchronous CDMA (TD-SCDMA), CDMA2000, or some other version of CDMA. For simplicity, FIG. 1 shows the wireless communication system 120 including two base stations 130 and 132 and one system controller 140. In general, a wireless system may include any number of base stations and any number of network entities.

A wireless device 110 may be referred to as a user equipment (UE), a mobile station, a terminal, an access terminal, a subscriber unit, a station, etc. The wireless device 110 may also be a cellular phone, a smartphone, a tablet, a wireless modem, a personal digital assistant (PDA), a handheld device, a laptop computer, a Smartbook, a netbook, a cordless phone, a wireless local loop (WLL) station, a Bluetooth device, etc. The wireless device 110 may be capable of communicating with the wireless communication system 120. The wireless device 110 may also be capable of receiving signals from broadcast stations (e.g., a broadcast station 134), signals from satellites (e.g., a satellite 150) in one or more global navigation satellite systems (GNSS), etc. The wireless device 110 may support one or more radio technologies for wireless communication such as 5G, LTE, CDMA2000, WCDMA, TD-SCDMA, GSM, 802.11, etc.

The wireless device 110 may support carrier aggregation, which is operation on multiple carriers. Carrier aggregation may also be referred to as multi-carrier operation. According to an aspect of the present disclosure, the wireless device 110 may be able to operate in low-band from 698 to 960 megahertz (MHz), mid-band from 1475 to 2170 MHz, and/or high-band from 2300 to 2690 MHz, ultra-high band from 3400 to 3800 MHz, and long-term evolution (LTE) in LTE unlicensed bands (LTE-U/LAA) from 5150 MHz to 5950 MHz. Low-band, mid-band, high-band, ultra-high band, and LTE-U refer to five groups of bands (or band groups), with each band group including a number of frequency bands (or simply, “bands”). For example, in some systems each band may cover up to 200 MHz and may include one or more carriers. For example, each carrier may cover up to 40 MHz in LTE. Of course, the range for each of the bands is merely exemplary and not limiting, and other frequency ranges may be used. LTE Release 11 supports 35 bands, which are referred to as LTE/UMTS bands and are listed in 3GPP TS 36.101. The wireless device 110 may be configured with up to five (5) carriers in one or two bands in LTE Release 11.

FIG. 2 shows a block diagram of an exemplary design of a wireless device 200, such as the wireless device 110 shown in FIG. 1. FIG. 2 shows an example of a transceiver 220, which may be a wireless transceiver (WTR). In general, the conditioning of the signals in a transmitter 230 and a receiver 250 may be performed by one or more stages of amplifier(s), filter(s), upconverters, downconverters, and the like. These circuit blocks may be arranged differently from the configuration shown in FIG. 2. Furthermore, other circuit blocks not shown in FIG. 2 may also be used to condition the signals in the transmitter 230 and receiver 250. Unless otherwise noted, any signal in FIG. 2, or any other illustrations in the drawings, may be either single-ended or differential. Some circuit blocks in FIG. 2 may also be omitted.

In the example shown in FIG. 2, the wireless device 200 generally includes the transceiver 220 and a data processor 210. The data processor 210 may include a memory (not shown) to store data and program codes, and may generally include analog and digital processing elements. The transceiver 220 may include the transmitter 230 and receiver 250 that support bi-directional communication. In general, the wireless device 200 may include any number of transmitters and/or receivers for any number of communication systems and frequency bands. All or a portion of the transceiver 220 may be implemented on one or more analog integrated circuits (ICs), radio frequency (RF) integrated circuits (RFICs), mixed-signal ICs, and the like.

A transmitter or a receiver may be implemented with a super-heterodyne architecture or a direct-conversion architecture. In the super-heterodyne architecture, a signal is frequency-converted between radio frequency and baseband in multiple stages (e.g., from radio frequency to an intermediate frequency (IF) in one stage, and from intermediate frequency to baseband in another stage for a receiver). In the direct-conversion architecture, a signal is frequency-converted between radio frequency and baseband in one stage. The super-heterodyne and direct-conversion architectures may use different circuit blocks and/or have different requirements. In the example shown in FIG. 2, the transmitter 230 and the receiver 250 are implemented with the direct-conversion architecture.

In a transmit path, the data processor 210 processes data to be transmitted. The data processor 210 also provides in-phase (I) and quadrature (Q) analog output signals to the transmitter 230 in the transmit path. In an exemplary aspect, the data processor 210 includes digital-to-analog converters (DACs) 214a and 214b for converting digital signals generated by the data processor 210 into the in-phase (I) and quadrature (Q) analog output signals (e.g., I and Q output currents) for further processing.

Within the transmitter 230, lowpass filters 232a and 232b filter the in-phase (I) and quadrature (Q) analog transmit signals, respectively, to reduce undesired images caused by the prior digital-to-analog conversion. Amplifiers (Amp) 234a and 234b amplify the signals from lowpass filters 232a and 232b, respectively, and provide in-phase (I) and quadrature (Q) baseband signals. An upconverter 240 including upconversion mixers 241a and 241b upconverts the in-phase (I) and quadrature (Q) baseband signals with in-phase (I) and quadrature (Q) transmit (TX) local oscillator (LO) signals from a TX LO signal generator 290 to provide an upconverted signal. A filter 242 filters the upconverted signal to reduce undesired images caused by the frequency upconversion as well as interference in a receive frequency band. A power amplifier (PA) 244 amplifies the signal from filter 242 to obtain the desired output power level and provides a transmit radio frequency signal. The transmit radio frequency signal is routed through a duplexer/switch 246 and transmitted via an antenna 248.

In a receive path, the antenna 248 receives communication signals and provides a received radio frequency (RF) signal, which is routed through the duplexer/switch 246 and provided to a low noise amplifier (LNA) 252. The duplexer/switch 246 is designed to operate with a specific receive (RX) to transmit (TX) (RX-to-TX) duplexer frequency separation, such that RX signals are isolated from TX signals. The received RF signal is amplified by the LNA 252 and filtered by a filter 254 to obtain a desired RF input signal. Downconversion mixers 261a and 261b mix the output of the filter 254 with in-phase (I) and quadrature (Q) receive (RX) LO signals (i.e., LO_I and LO_Q) from an RX LO signal generator 280 to generate in-phase (I) and quadrature (Q) baseband signals. The in-phase (I) and quadrature (Q) baseband signals are amplified by amplifiers 262a and 262b and further filtered by lowpass filters 264a and 264b to obtain in-phase (I) and quadrature (Q) analog input signals, which are provided to the data processor 210. In the exemplary configuration shown, the data processor 210 includes analog-to-digital converters (ADCs) 216a and 216b for converting the analog input signals into digital signals for further processing by the data processor 210.

In FIG. 2, the transmit local oscillator (TX LO) signal generator 290 generates the in-phase (I) and quadrature (Q) TX LO signals used for frequency upconversion, while a receive local oscillator (RX LO) signal generator 280 generates the in-phase (I) and quadrature (Q) RX LO signals used for frequency downconversion. Each LO signal is a periodic signal with a particular fundamental frequency. A phase locked loop (PLL) 292 receives timing information from the data processor 210 and generates a control signal used to adjust the frequency and/or phase of the TX LO signals from the TX LO signal generator 290. Similarly, a PLL 282 receives timing information from the data processor 210 and generates a control signal used to adjust the frequency and/or phase of the RX LO signals from the RX LO signal generator 280.

The wireless device 200 may support carrier aggregation and may (i) receive multiple downlink signals transmitted by one or more cells on multiple downlink carriers at different frequencies, and/or (ii) transmit multiple uplink signals to one or more cells on multiple uplink carriers. For intra-band carrier aggregation, the transmissions are sent on different carriers in the same band. For inter-band carrier aggregation, the transmissions are sent on multiple carriers in different bands. Those skilled in the art will understand, however, that aspects described herein may be implemented in systems, devices, and/or architectures that do not support carrier aggregation.

FIG. 3 shows various gate resistance components for a fin structure 300 including multiple fins. The gate resistance components include vertical and horizontal components. The resistance of the fin structure 300 may include a vertical component and a horizontal component. The resistances are deemed vertical or horizontal based on an orientation of the fin structure 300. For example, the fin structure 300 includes fins 302a, 302b, 302c, and 302d that have vertical and horizontal resistances. In this orientation of the fin structure 300, resistances R1, R2, R3, and R4 are deemed horizontal resistances while resistances R5, R6, R7, and R8 are deemed vertical resistances. Although the resistances are illustrated as vertical and horizontal resistances, the resistances are not limited to those two components. However, for illustrative and explanatory purposes every gate resistance part is lumped into vertical and horizontal components.

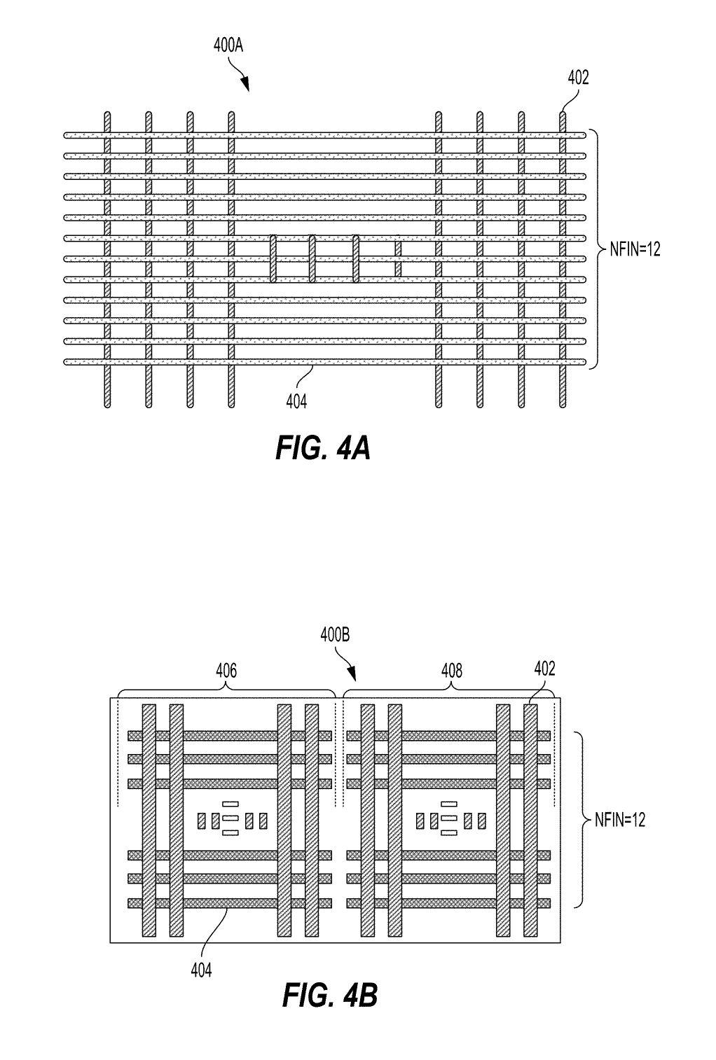

FIG. 4A is an illustration of a FinMosVar (fin metal oxide semiconductor (MOS) varactor) 400A having a fin structure with twelve fins, according to aspects of the present disclosure. The FinMosVar includes gates 402 and fins 404. In one aspect of the disclosure, the number of fins 404 of the FinMosVar 400A is less than twenty. In other aspects, the number of fins 404 of the FinMosVar is eleven to thirteen fins, as illustrated in FIG. 4A. For example, FIG. 4A is an illustration of the FinMosVar 400A with twelve fins 404. The gates 402 may be polysilicon or high-K metal, for example.

FIG. 4B is an illustration of a FinMosVar (fin metal oxide semiconductor (MOS) varactor) 400B including multiple devices 406, 408 coupled in parallel, according to aspects of the present disclosure. Similar to the FinMosVar 400A, each device 406 and 408 of the FinMosVar 400B include fins 404 and gates 402. For example, the FinMosVar 400B includes parallel fin structures, each with less than twenty fins. In one aspect, each of the parallel fin structures includes eleven to thirteen (e.g., twelve) fins, as shown in FIG. 4B.

The devices of the FinMosVar may be coupled in parallel to achieve an increased capacitance. In one aspect, the first device 406 is coupled to the second device 408 via back-end-of-line connections. For example, drains of the first device 406 may be coupled to drains of the second device 408. Sources of the first device 406 may be coupled to sources of the second device 408. Similarly, gates 402 of the first device 406 may be coupled to gates 402 of the second device 408.

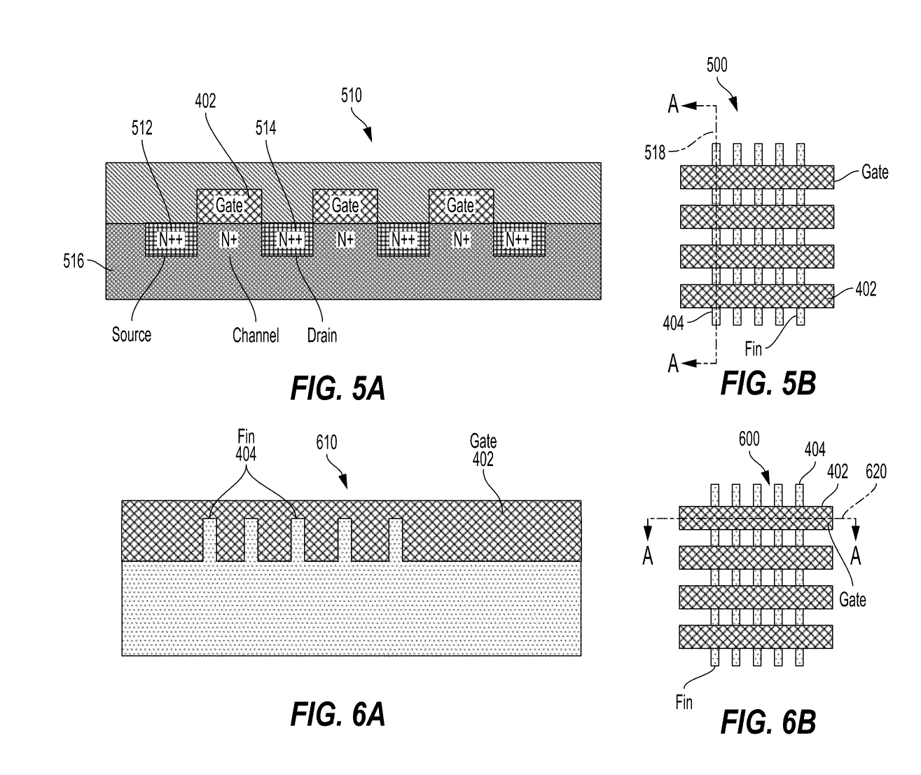

FIGS. 5A and 5B illustrates a corresponding cross-sectional view 510 through a fin of the FinMosVar 500 and an exemplary top view of a FinMosVar 500, according to aspects of the present disclosure. For illustrative purposes, some of the labelling and numbering of the devices and features of FIGS. 5A and 5B are similar to those of FIGS. 4A and 4B. The cross-sectional view 510 cuts along a line 518 through a fin 404 of the FinMosVar 500. The FinMosVar 500 shown in its cross-sectional view 510 includes a drain 514, a gate 402, a source 512, and a channel 516. The channel 516 is at least partially formed between the source 512 and the drain 514. The drain 514, the source 512, and the channel 516 of the FinMosVar 500 are fabricated with a same type of doping. For example, the drain 514, the source 512, and the channel 516 are doped with an N-type doping. In this aspect, the drain 514 and the source 512 have more of the N-type doping (N++) than the doping (N+) of the channel 516. The difference in the N-type doping between the channel 516 (N+) and the source 512 (N++) or the drain 514 (N++) may be to reduce resistances associated with the source 512 and the drain 514. In some aspects, however, the doping of the source, the drain and the channel are the same type.

FIGS. 6A and 6B illustrates a corresponding cross-sectional view 610 through a gate 402 of the FinMosVar 600 and an exemplary top view of a FinMosVar 600, according to aspects of the present disclosure. For illustrative purposes, some of the labelling and numbering of the devices and features of FIGS. 6A and 6B are similar to those of FIGS. 4A and 4B. The cross-sectional view 610 cuts along a line 620 through the gate 402 of the FinMosVar 600. Although the number of fins 404 illustrated in the FinMosVar 500 and the FinMosVar 600 (and corresponding cross-sectional views 510 and 610) is five, the number of fins 404, according to aspects of the present disclosure, may be more or less than five. For example, the number of fins may be less than twenty. Particularly, the number of fins may be between eleven and thirteen.

Aspects of the present disclosure achieve an improved number of fins (for a specified number of gates e.g., sixty) with a fifteen percent (15%) lower gate resistance (Rgate), as illustrated in Table 1.

For example, Table 1 illustrates measurements or calculations of different gate resistances (Rgate) for different FinMosVar devices with different numbers of fins (NFIN) and gates (NF) under radio frequency conditions. Comparing a gate resistance of a FinMosVar having twelve fins and sixty gates to a gate resistance of a FinMosVar having twenty fins and sixty gates, the FinMosVar with twelve fins has a fifteen percent lower gate resistance than the FinMosVar with twenty fins.

Aspects of the present disclosure achieve an improved number of fins (for a specified number of gates, e.g., sixty) with a forty percent (40%) lower capacitance, as illustrated in Table 2.

TABLE 2

| NF | NFIN | Capacitance |
|---|---|---|
| 60 | 12 | 39.59 |
| 60 | 21 | 69.2 |
| 60 | 31 | 102.1 |
| 60 | 41 | 135 |

Table 2 illustrates measurements or calculation results of different FinMosVar capacitances for different FinMosVar devices with different numbers of fins (NFIN) and a same number of gates (NF) under radio frequency conditions. Comparing a FinMosVar capacitance of a FinMosVar having twelve fins and sixty gates to a FinMosVar capacitance of a FinMosVar having twenty-one fins and sixty gates, the FinMosVar with twelve fins has a forty percent lower capacitance than the FinMosVar with twenty one fins.

The combination of the benefits of the lower gate resistance and the lower capacitance effectively results in a FinMosVar that can have up to two hundred percent (200%) higher Q-factor. The benefits of the optimized or improved FinMosVar are achieved without additional manufacturing cost and without negative impact to other parts of the chip. The FinMosVar can be used in radio frequency chips, such as receivers, transceivers, etc.

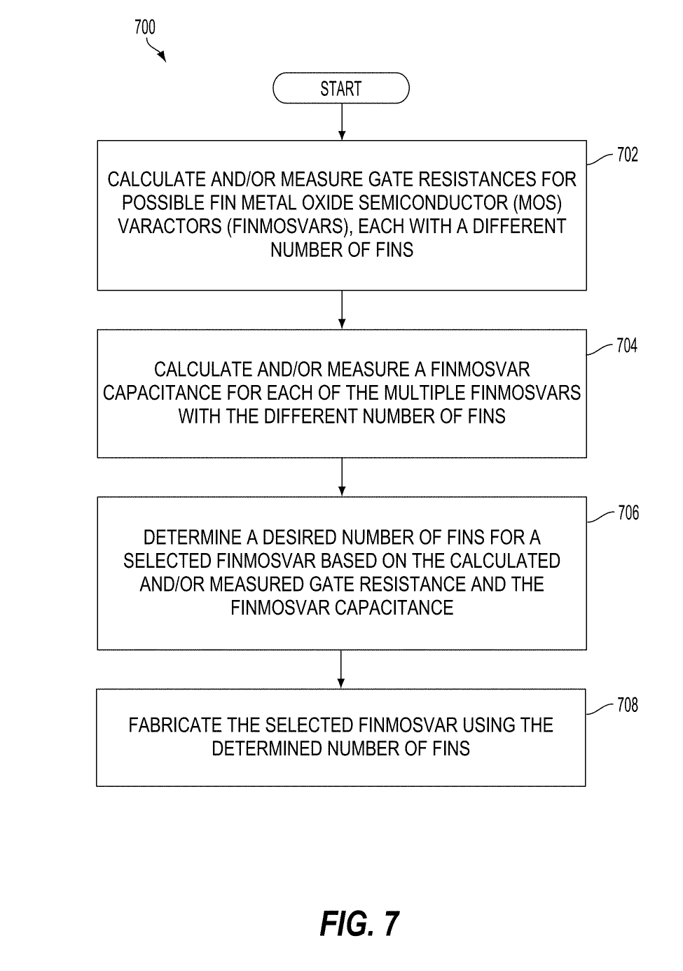

FIG. 7 depicts a simplified flowchart of a method 700 of manufacturing a FinMosVar (fin metal oxide semiconductor (MOS) varactor). At block 702, gate resistances (Rgate) for possible FinMosVars with different numbers of fins is calculated and/or measured. At block 704, a FinMosVar capacitance for each varactor with the different number of fins is calculated and/or measured. At block 706, a desired number of fins for the varactor is determined based on the calculated and/or measured gate resistances and FinMosVar capacitances. At block 708, the FinMosVar is fabricated using the determined number of fins.

According to one aspect of the present disclosure, a FinMosVar (fin metal oxide semiconductor (MOS) varactor) is described. The FinMosVar includes means for carrying charge between the drain region and the source region. The charge carrying means may, for example, be the channel region, and/or the channel 516. In another aspect, the aforementioned means may be any module or any apparatus or material configured to perform the functions recited by the aforementioned means.

FIG. 8 is a block diagram showing an exemplary wireless communication system in which a configuration of the disclosure may be advantageously employed. For purposes of illustration, FIG. 8 shows three remote units 820, 830, and 850 and two base stations 840. It will be recognized that wireless communication systems may have many more remote units and base stations. Remote units 820, 830, and 850 include IC devices 825A, 825B, and 825C such as the disclosed FinMosVar. It will be recognized that other devices may also include the disclosed FinMosVar, such as the base stations, switching devices, and network equipment. FIG. 8 shows forward link signals 880 from the base station 840 to the remote units 820, 830, and 850 and reverse link signals 890 from the remote units 820, 830, and 850 to base station 840.

In FIG. 8, remote unit 820 is shown as a mobile telephone, remote unit 830 is shown as a portable computer, and remote unit 850 is shown as a fixed location remote unit in a wireless local loop system. For example, a remote unit may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieves data or computer instructions, or combinations thereof Although FIG. 8 illustrates remote units according to the aspects of the disclosure, the disclosure is not limited to these exemplary illustrated units. Aspects of the disclosure may be suitably employed in many devices, which include the FinMosVar.

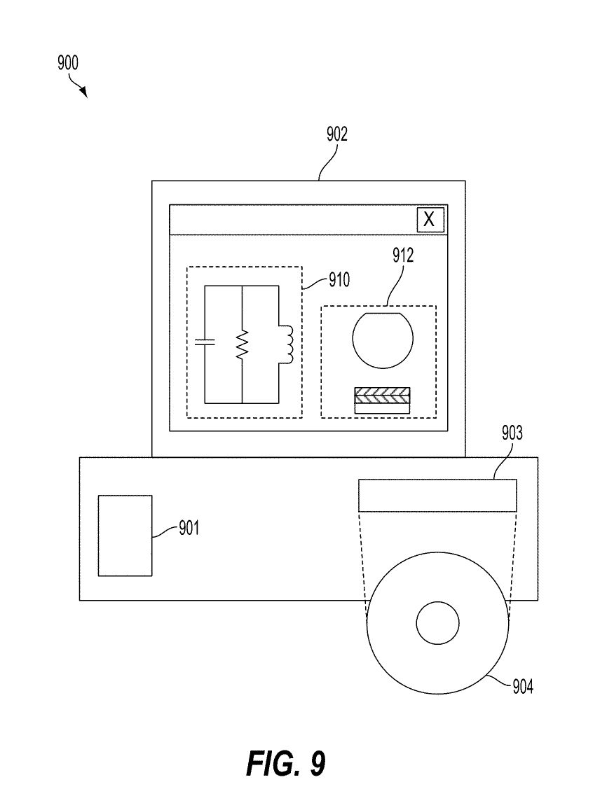

FIG. 9 is a block diagram illustrating a design workstation used for circuit, layout, and logic design of the FinMosVar disclosed above. A design workstation 900 includes a hard disk 901 containing operating system software, support files, and design software such as Cadence or OrCAD. The design workstation 900 also includes a display 902 to facilitate design of a circuit 910 or a FinMosVar. A storage medium 904 is provided for tangibly storing the design of the circuit 910 or the FinMosVar. The design of the circuit 910 or the FinMosVar may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit 910 or the FinMosVar by decreasing the number of processes for designing semiconductor or passive wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long-term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A method of manufacturing a selected FinMosVar (fin metal oxide semiconductor (MOS) varactor), comprising:
measuring and/or calculating gate resistances (Rgate) for a plurality of possible FinMosVar devices, each with a different number of fins;
measuring and/or calculating a FinMosVar capacitance for each of the plurality of FinMosVar devices with the different number of fins;
determining a desired number of fins for the selected FinMosVar based at least in part on the measured and/or calculated gate resistances and the FinMosVar capacitances; and
fabricating the selected FinMosVar using the desired number of fins.

2. The method of claim 1, in which the gate resistances each comprise a vertical resistance and a horizontal resistance.

3. The method of claim 1, further comprising measuring and/or calculating the gate resistances and the FinMosVar capacitances to determine the desired number of fins under radio frequency conditions.

4. The method of claim 3, in which the radio frequency conditions include five gigahertz (GHz) radio frequency conditions.

5. The method of claim 1, in which fabricating the FinMosVar further comprises fabricating a drain region, a source region and a channel region with a same type of doping.

6. The method of claim 1, further comprising fabricating the selected FinMosVar in accordance with a sixteen nanometer (nm), a fourteen nanometer, a ten nanometer, a seven nanometer, or a five nanometer fin process technology.

7. The method of claim 1, further comprising fabricating a second selected FinMosVar in parallel to the selected FinMosVar.

8. A FinMosVar (fin metal oxide semiconductor (MOS) varactor), comprising:
a number of fins determined based at least in part on a measured or calculated gate resistance of the FinMosVar and a measured or calculated capacitance of the FinMosVar, in which the number of fins is less than twenty (20) fins;
a source region;
a drain region having a same type of doping as the source region; and
a channel region having the same type of doping as the source region.

9. The FinMosVar of claim 8, in which the number of fins comprises eleven to thirteen (11-13) fins.

10. The FinMosVar of claim 8, coupled to a plurality of parallel devices, each with less than twenty fins.

11. The FinMosVar of claim 10, in which each of the parallel devices comprises eleven to thirteen fins.

12. A FinMosVar (fin metal oxide semiconductor (MOS) varactor), comprising:
a number of fins determined based at least in part on a measured or calculated gate resistance of the FinMosVar and a measured or calculated capacitance of the FinMosVar, in which the number of fins is less than twenty (20) fins;
a source region;
a drain region having a same type of doping as the source region; and
means for carrying charge in the between the drain region and the source region, the charge carrying means having the same type of doping as the source region.

13. The FinMosVar of claim 12, in which the number of fins comprises eleven to thirteen (11-13) fins.

14. The FinMosVar of claim 12, coupled to a plurality of parallel devices, each with less than twenty fins.

15. The FinMosVar of claim 14, in which each of the parallel devices comprises eleven to thirteen fins.
